(19) United States
(12) Patent Application Publication
(10) Pub. No.: US 2011/0248702 A1
(43) Pub. Date: Oct. 13, 2011

(54) CURRENT DETECTION CIRCUIT INCLUDING ELECTROSTATIC CAPACITOR AND RECTIFYING ELEMENT FOR INCREASING GATE VOLTAGE OF PROTECTING MOSFET

(76) Inventor: Tomohiro KUME, Osaka (JP)

(21) Appl. No.: 13/081,781

(22) Filed: Apr. 7, 2011

(30) Foreign Application Priority Data
Apr. 7, 2010 (JP) 2010-088724

(51) Int. Cl. G01R 19/22

(52) U.S. Cl. 324/119

(57) ABSTRACT

Using a electrostatic capacitor and a diode, a gate voltage of a protecting MOSFET is increased when a drain voltage of a power transistor increases. A voltage clamp circuit clamps the maximum voltage of the gate voltage of the protecting MOSFET to a predetermined clamp voltage. A voltage control circuit controls a drain voltage of a sense transistor so as to substantially coincide with a source voltage of the protecting MOSFET.

The disclosure of Japanese Patent Application No. 2010-088724 filed Apr. 7, 2010 including specification, drawings and claims is incorporated herein by reference in its entirety.

### BACKGROUND OF THE INVENTION

1. Field of the Invention

The present invention relates to a current detection circuit for detecting a value of a current flowing through a power semiconductor device.

2. Description of the Related Art

Power semiconductor devices (referred to as power transistors hereinafter) such as thyristors are used for power conversion and power control. For example, the power semiconductor devices are often used as power control devices for use in driving devices for inverter control of motors, or power control devices for use in switching power supplies. Concretely speaking, a current flowing through a power transistor is used for generating a driving torque of a motor load. In the switching power supply, the power transistor is used for improving response of the switching power supply. In particular, an Insulated Gate Bipolar Transistor (IGBT) and a power Metal Oxide Semiconductor Field Effect Transistor (MOSFET) can perform high-speed switching with a switching speed higher than that of a bipolar junction transistor (BJT) or a thyristor. Therefore, the IGBT and the power MOSFET have been used also in the field of high withstand voltage where the BJT or the thyristor has conventionally been used. Further, in recent years, power semiconductor devices, that have a high withstand voltage and are able to perform the high-speed switching, have been developed by employing a wide bandgap semiconductor using silicon carbide (SiC) or gallium nitride (GaN) in place of the conventional silicon semiconductors.

An excessive current applied to a load when abnormality occurs deteriorates or damages the load or the power transistor connected to the load. Therefore, in a circuit employing a power transistor, the following techniques are required: a technique of detecting the current flowing through the power transistor and controlling the current flowing through the load based on a detected current; and an overcurrent detection technique of cutting off the current flowing through the power transistor to protect the power transistor when a current value of the detected current is larger than a predetermined value. Generally speaking, in order to detect the current flowing through the power transistor, a device is provided in parallel to the power transistor which supplies a current to the load, where the device has the same structure as that of the power transistor and has a dimension smaller than that of the power transistor. This device having the small dimension is called a sense transistor, since it is provided to sense (detect) the current flowing through the power transistor. Concretely speaking, when the power transistor and the sense transistor have a Field Effect Transistor (FET) structure and have channel lengths the same as each other and channel widths different from each other, it is possible to obtain a current substantially proportional to the channel width of the sense transistor by connecting gates of the power transistor and the sense transistor to each other so that the gates have electrical potentials the same as each other, and by making drains or sources of the power transistor and the sense transistor have electrical potentials the same as each other.

For example, when the drains of the power transistor and the sense transistor have the electrical potentials the same as each other, a part of the current flowing through the load connected to the drain of the power transistor is supplied to and detected by the sense transistor that has a channel width smaller than the channel width of the power transistor. In this case, a source-drain current flowing through the sense transistor is substantially proportional to a load current. By applying a detected current to a resistor element or one terminal of a measuring resistor, which is another transistor operating in a resistive region (also called a triode region or a linear region), the detected current is taken out as a minute voltage. Since an electrical potential of another terminal of the measuring resistor is normally set to an electrical potential the same as that of the source of the power transistor, the one terminal of the measuring resistor has an electrical potential lowered from the source electrical potential of the sense transistor by a voltage drop due to the measuring resistor.

Next, with reference to FIG. 8, operation of the current detection circuit when the sources of the power transistor and the sense transistor have the electrical potentials the same as each other is described. FIG. 8 is a circuit diagram of a prior art current detection circuit, which is described in Japanese patent laid-open publication No. JP-2007-121052-A.

The current detection circuit of FIG. 8 is configured to include a power MOSFET 101 corresponding to the aforementioned power transistor, a MOSFET 102 corresponding to the above-mentioned sense transistor, a differential amplifier (operational amplifier) 103, a zener diode 133, a zener diode 134, a MOSFET 106, an enhancement type (normally-off type) MOSFET 137, and an enhancement type MOSFET 138. In this case, a source of the power MOSFET 101 is grounded, and a drain of the power MOSFET 101 is connected to a power source 112 via a terminal 108, a load 104 and a terminal 111. A source of the sense MOSFET 102 is grounded, and a drain of the sense MOSFET 102 is connected to a power source 113 via the MOSFET 106, a terminal 110 and a measuring resistor 105. Further, gates of the power MOSFET 101 and the sense MOSFET 102 are connected to an input terminal 109 for applying a control voltage. The zener diode 133 has an anode connected to the source of the power MOSFET 101, and a cathode connected to a non-inverted input terminal of the differential amplifier 103. The zener diode 134 has an anode connected to the source of the power MOSFET 101, and a cathode connected to an inverted input terminal of the differential amplifier 103. An output terminal of the differential amplifier 103 is connected to a gate of the MOSFET 106. The enhancement type MOSFET 137 is connected between the drain of the power MOSFET 101 and the non-inverted input terminal of the differential amplifier 103, the enhancement type MOSFET 138 is connected between the drain of the sense MOSFET 102 and the inverted input terminal of the differential amplifier 103, and the gates of the enhancement type MOSFETs 137 and 138 are grounded via a voltage source 135.

Referring to FIG. 8, the drain of the power MOSFET 101 supplies a current to the load 104, and a drain current of the sense MOSFET 102 is substantially proportional to the current flowing through the load 104. In this case, an accuracy of a current ratio is reduced due to variations in a values of channel width and channel length caused by a positional mismatch of the layout, fluctuations in the drain current caused by a phenomenon that an output impedance is reduced by a channel length modulation due to a difference in the drain voltages of the power MOSFET 101 and the sense MOSFET 102, a resistance drop in wirings caused by a relatively large current, and so on. In the current detection circuit of FIG. 8, in order to partially compensate for the reduction in the accuracy of the current ratio, the differential amplifier 103 is used as a negative feedback amplifier for a balance between a drain-source voltage of the sense MOSFET 102 and a drain-source voltage of the power MOSFET 101 so that the drain-source voltage of the sense MOSFET 102 coincides with the drain-source voltage of the power MOSFET 101. Then, a load current value proportional to the ratio of the size of the sense MOSFET 101 to the size of the power MOSFET 102 is detected. Further, referring to FIG. 8, in order to prevent a voltage larger than an allowable input voltage of the differential amplifier 103 from being applied to the differential amplifier 103 as a result of application of a high voltage between the drain and the source of the power MOSFET 101 when the power MOSFET 101 is cut off, the enhancement type MOSFET 137 and the zener diode 133 are provided. According to the current detection circuit of FIG. 8, when the high voltage is applied to the drain of the power MOSFET 101, the MOSFET 137 is cut off, and an input voltage of equal to or larger than an operating range is not applied to the differential amplifier 103. Therefore, it is possible to prevent an excessive voltage from being applied to the input terminal of the differential amplifier 103.

However, when the current detection circuit of FIG. 8 is implemented with an integrated circuit, an electrical potential of a substrate of the enhancement type MOSFET 137, which is the protection device of the differential amplifier 103, is made common to a ground potential of the integrated circuit. Therefore, due to a substrate bias effect, a gate threshold voltage of the enhancement type MOSFET 137 changes to a value (e.g., 2 V) larger than the gate threshold voltage (e.g., 0.8 V) in such a state in which the substrate and the source of the enhancement type MOSFET 137 have electrical potentials the same as each other, namely, a substrate bias is zero. Therefore, when the current detection circuit of FIG. 8 is implemented by the integrated circuit, the gate threshold voltage of the enhancement type MOSFET 137 disadvantageously becomes very larger than the gate threshold voltage when the enhancement type MOSFET 137 is implemented by an individual component.

Referring to FIG. 8, when a source of the enhancement type MOSFET 137 is connected to the non-inverted input terminal of the differential amplifier 103, and a drain of the enhancement type MOSFET 137 is connected to the drain of the power MOSFET 101, the following problems occur due to the above-mentioned substrate bias effect. First of all, a source voltage of the enhancement type MOSFET 137 does not become larger than a voltage which is lower than a gate voltage by the gate threshold voltage. This leads to such a problem that a detection voltage range of a drain voltage of the power MOSFET 101 is disadvantageously narrowed than a detection voltage range when there is no substrate bias effect. In addition, even when a voltage higher than a detection voltage is applied to the drain of the enhancement type MOSFET 137, the source voltage (i.e., a voltage outputted to the non-inverted input terminal of the differential amplifier 103) is limited to a voltage which is lower than the gate application voltage by the gate threshold voltage raised by the substrate bias effect. Then, the drain voltage of the sense MOSFET 102 is controlled to be a voltage almost equal to the voltage outputted to the non-inverted input terminal of the differential amplifier 103 by a negative feedback. Therefore, the drain voltages of the power MOSFET 101 and the sense MOSFET 102 become different from each other, and a ratio of the drain current of the power MOSFET 101 to the drain current of the sense MOSFET 102 becomes different from the ratio of size of the power MOSFET 101 to the size of the sense MOSFET 102. As a result, there is caused such a problem that a current detection accuracy is reduced.

On the other hand, by raising the application voltage to the gate of the enhancement type MOSFET 137 by an amount of change in the gate threshold voltage due to the substrate bias effect, it is possible to increase the source voltage up to a sufficient voltage easily. However, even when a withstand voltage between the drain and the gate of the enhancement type MOSFET 137 and a withstand voltage between the drain and the substrate of the enhancement type MOSFET 137 are raised with an LDD (Lightly Doped Drain) structure or the like, a withstand voltage between the source and the gate is normally the lowest in the integrated circuit in order to increase transconductance. Therefore, only a voltage of equal to or smaller than the withstand voltage between the source and the gate can be applied to the gate of the enhancement type MOSFET 137 with respect to the lowest voltage value of the source voltage. Therefore, it is not necessarily allowed to apply a high voltage to the gate of the enhancement type MOSFET 137.

### SUMMARY OF THE INVENTION

Accordingly, it is an object of the present invention to provide a current detection circuit capable of solving the above-mentioned problems, and including a power transistor having a first terminal and a second terminal, a sense transistor having a fourth terminal and a third terminal connected to the first terminal, an operational amplifier to make the voltage at the fourth terminal coincide with the voltage at the second terminal, and a protecting MOSFET for protecting the operational amplifier from an overvoltage. In particular, it is an object of the present invention to provide a current detection circuit capable of solving the above-mentioned problems, and capable of detecting a load current with an accuracy higher than that of the prior art with exercising negative feedback to a relatively high voltage by the operational amplifier while satisfying the withstand voltage between the source and the gate of the protecting MOSFET, even when the substrate bias effect occurs in the protecting MOSFET due to implementation of the current detection circuit with an integrated circuit.

In order to achieve the above-mentioned objective, according to one aspect of the present invention, there is provided a current detection circuit including:

a first semiconductor device having a first terminal, a second terminal, and a first current control terminal, a current flowing between the first and second terminals being controlled by a control voltage applied to the first current control terminal;

a second semiconductor device having a third terminal connected to the first terminal, a fourth terminal, and a second current control terminal the second semiconductor device having a structure substantially the same as a structure of the first semiconductor device, a current flowing between the third and fourth terminals being controlled by the control voltage applied to the second current control terminal;

a MOS field-effect transistor having a drain connected to the second terminal of the first semiconductor device, a source, and a gate, a current flowing between the drain and the source being controlled by a voltage applied to the gate;

an electrostatic capacitor having one end connected to the source of the MOS field-effect transistor, and another end connected to the gate of the MOS field-effect transistor;

a rectifying element having a cathode connected to the gate of the MOS field-effect transistor and an anode connected to a first voltage source for outputting a predetermined first power voltage;

a voltage clamp circuit connected to the gate of the MOS field-effect transistor, the voltage clamp circuit clamping a maximum voltage of the gate of the MOS field-effect transistor to a predetermined clamp voltage;

a voltage control circuit for controlling a voltage at the fourth terminal of the second semiconductor device so as to substantially coincides with a source voltage of the MOS field-effect transistor; and

a detector circuit for detecting a current flowing through the fourth terminal of the second semiconductor device.

The above-mentioned current detection circuit preferably further includes a load connected to the second terminal of the first semiconductor device, and the first terminal of the first semiconductor device and the third terminal of the second semiconductor device are grounded.

In addition, the above-mentioned current detection circuit preferably further includes a load connected to the first terminal of the first semiconductor device, and the second terminal of the first semiconductor device and the drain of the MOS field-effect transistor are connected to a second voltage source for outputting a predetermined second power voltage.

Further, the above-mentioned current detection circuit preferably further includes a driver circuit for applying the control voltage to the first and second current control terminals.

Still further, in the above-mentioned current detection circuit, the voltage control circuit preferably includes:

an operational amplifier having a non-inverted input terminal connected to the source of the MOS field-effect transistor, an inverted input terminal connected to the fourth terminal of the second semiconductor device, and an output terminal; and

an output transistor having a fifth terminal connected to the fourth terminal of the second semiconductor device, a sixth terminal connected to the detector circuit, and a third current control terminal connected to the output terminal of the operational amplifier, a current flowing between the fifth and sixth terminals being controlled by a voltage applied from the operational amplifier to the third current control terminal.

According to the current detection circuit of the present invention, the circuit includes the followings:

(a) the MOSFET transistor having the drain connected to the second terminal of the first semiconductor device, the source and the gate, where current flowing between the drain and the source is controlled by the voltage applied to the gate;

(b) the electrostatic capacitor having one end connected to the source of the MOSFET transistor and another end connected to the gate of the MOSFET transistor;

(c) the rectifier device having a cathode connected to the gate of the MOSFET transistor and an anode connected to the first voltage source for outputting the predetermined first power voltage; and

(d) the voltage clamp circuit connected to the gate of the MOSFET transistor, where the voltage clamp circuit clamping the maximum voltage of the gate of the MOSFET transistor to the predetermined clamp voltage.

With this arrangement, it is possible to apply a gate threshold voltage, which is increased by the substrate bias effect, to the gate of the MOSFET transistor in addition to the source voltage. Therefore, even when the substrate bias effect in the MOSFET transistor is relatively large, the load current can be detected with an accuracy higher than that of the prior art with exercising negative feedback to the relatively high voltage while satisfying the withstand voltage between the source and the gate of the MOSFET transistor.

### BRIEF DESCRIPTION OF THE DRAWINGS

These and other objects and features of the present invention will become clear from the following description taken in conjunction with the preferred embodiments thereof with reference to the accompanying drawings throughout which like parts are designated by like reference numerals, and in which:

FIG. 1 is a circuit diagram of a current detection circuit according to a first preferred embodiment of the present invention;

FIG. 2 is a circuit diagram of a current detection circuit according to a first modified preferred embodiment of the first preferred embodiment of the present invention;

FIG. 3 is a circuit diagram of a current detection circuit according to a second modified preferred embodiment of the first preferred embodiment of the present invention;

FIG. 4 is a circuit diagram of a current detection circuit according to a third modified preferred embodiment of the first preferred embodiment of the present invention;

FIG. 5 is a circuit diagram of a current detection circuit according to a fourth modified preferred embodiment of the first preferred embodiment of the present invention;

FIG. 6 is a circuit diagram of a current detection circuit according to a fifth modified preferred embodiment of the first preferred embodiment of the present invention;

FIG. 7 is a circuit diagram of a current detection circuit according to a second preferred embodiment of the present invention; and

FIG. 8 is a circuit diagram of a prior art current detection circuit.

### DETAILED DESCRIPTION OF THE PREFERRED EMBODIMENTS

Preferred embodiments according to the present invention will be described below with reference to the attached drawings. Components similar to each other are denoted by the same reference numerals and will not be described herein in detail. In addition, the field-effect transistor is referred to as an FET hereinafter.

### First Preferred Embodiment

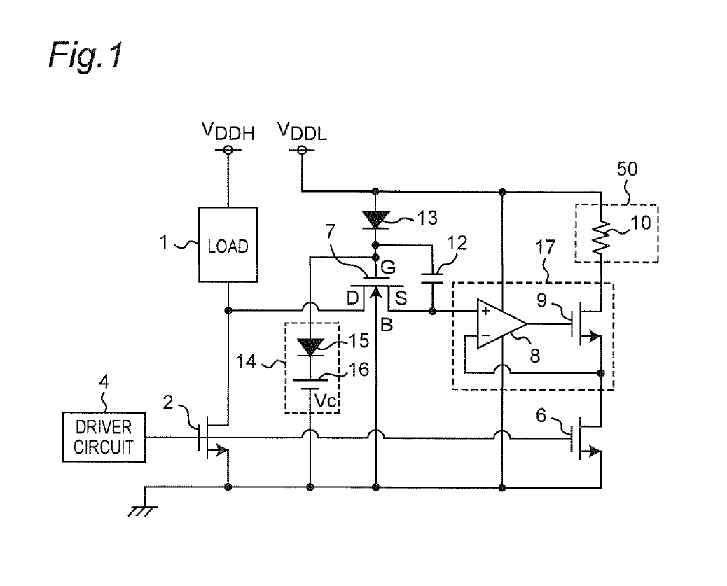

FIG. 1 is a circuit diagram of a current detection circuit according to the first preferred embodiment of the present invention. Referring to FIG. 1, the current detection circuit of the present preferred embodiment is an integrated circuit, and constituted by including a load 1, a power transistor 2, a sense transistor 6, a voltage control circuit 17 including an operational amplifier 8 and an output transistor 9, a detector circuit 50 including a resistor 10, a protecting MOSFET 7, a diode 13, an electrostatic capacitor 12, a voltage clamp circuit 14 including a diode 15 and a DC voltage source 16, and a driver circuit 4.

As described in detail later, the current detection circuit of the present preferred embodiment is characterized by including:

(a) the power transistor 2 having a source, a drain and a gate, where a current flowing between the source thereof and the drain thereof is controlled by a control voltage applied to the gate thereof;

(b) the sense transistor 6 having a source connected to the source of the power transistor 2, a drain and a gate, where the sense transistor 6 has a structure substantially the same as a structure of the power transistor 2, and a current flowing between the drain thereof and the source thereof is controlled by the control voltage applied to the gate thereof;

(c) the MOSFET 7 having a drain connected to the drain of the power transistor 2, a source and a gate, where a current flowing between the drain thereof and the source thereof is controlled by a voltage applied to the gate thereof;

(d) the electrostatic capacitor 12 having one end connected to the source of the MOSFET 7 and another end connected to the gate of the MOSFET 7;

(e) the diode 13 having a cathode connected to the gate of the MOSFET 7 and an anode connected to a voltage source for outputting a predetermined power voltage V_{DDL};

(f) the voltage clamp circuit 14 connected to the gate of the MOSFET 7, and clamps the maximum voltage of the gate of the MOSFET 7 to a predetermined clamp voltage Vc;

(g) the voltage control circuit 17 for controlling a drain voltage of the sense transistor 6 so as to substantially coincide with a source voltage of the MOSFET 7; and

(h) the detector circuit 50 for detecting a current flowing through the gate of the sense transistor 6.

Referring to FIG. 1, the load 1 is an inductive load (inductance) of, for example, a field coil of a motor or a coil of a switching power supply. In addition, in the present preferred embodiment, the power transistor 2 is an n-channel type MOS device, where the source of the power transistor 2 is grounded, the drain of the power transistor 2 is connected to a voltage source, which outputs a power voltage V_{DDH}, via the load 1, and the gate of the power transistor 2 is connected to the driver circuit 4. The driver circuit 4 makes the power transistor 2 perform switching operation by a control method of Pulse Width Modulation (PWM) or the like. The driver circuit 4 puts the power transistor 2 into its conductive state by applying a control voltage which exceeds a gate threshold voltage between the gate and the source of the power transistor 2, and the driver circuit 4 cuts off the power transistor 2 by applying a control voltage which is lower than the gate threshold voltage between the gate and the source of the power transistor 2, so as to make the power transistor 2 perform the switching operation. The power transistor 2 supplies a driving current from the drain thereof to the load 1 when being in its conductive state, and cuts off the driving current to the load 1 when being cut off. That is, the current flowing between the source and the drain of the power transistor 2 is controlled by the control voltage applied from the driver circuit 4 to the gate thereof. It is noted that the power voltage V_{DDH} is set to, for example, several hundreds of volts.

In addition, referring to FIG. 1, the sense transistor 6 has a structure substantially the same as the structure of the power transistor 2. Concretely speaking, the sense transistor 6 has a channel length the same as the channel length of the power transistor 2, and has a channel width substantially the same as the channel width of the power transistor 2 or a channel width smaller than the channel width of the power transistor 2. The sense transistor 6 has the source connected to the source of the power transistor 2, the gate connected to the gate of the power transistor 2, and the drain connected to the source of the output transistor 9 of an n-channel type MOSFET and to the inverted input terminal of the operational amplifier 8. A current flowing between the source and the drain of the sense transistor 6 is controlled by the control voltage applied from the driver circuit 4 to the gate.

Further, the drain of the output transistor 9 is connected to the voltage source, that outputs the power voltage V_{DDL}, via the resistor 10, and the gate is connected to the output terminal of the operational amplifier 8. In this case, the power voltage V_{DDL} is set to, for example, 12 V, and the operational amplifier 8 is driven by the power voltage V_{DDL}. Further, a substrate of the protecting MOSFET 7 is grounded, the drain thereof is connected to the drain of the power transistor 2, and the source thereof is connected to the non-inverted input terminal of the operational amplifier 8. It is noted that the protecting MOSFET 7 is an enhancement type MOSFET. In addition, between the drain and the source of the protecting MOSFET 7, the drain is selected as a terminal to which the higher voltage is applied. Therefore, as described in detail later, between the drain and the source of the protecting MOSFET 7, the terminal to which a high voltage comparable to the power voltage V_{DDH} is applied is only the drain. In order to raise a withstand voltage between the drain and the gate of the protecting MOSFET 7, the structure of the protecting MOSFET 7 has an LDD structure, for example.

Further, the electrostatic capacitor 12 is connected between the gate and the source of the protecting MOSFET 7. In addition, the anode of the diode 13 is connected to the voltage source that outputs the power voltage V_{DDL}, and the cathode of the diode 13 is connected to the gate of the protecting MOSFET 7. Further, the anode of the diode 15 is connected to the gate of the protecting MOSFET 7, and the cathode of the diode 15 is grounded via the DC voltage source 16. The DC voltage source 16 generates a predetermined clamp voltage Vc relative to a ground potential of a reference electric potential.

Referring to FIG. 1, when the power transistor 2 is in its conductive state, a current flows through the load 1, and the drain voltage of the power transistor 2 becomes a voltage such that a voltage drop due to the load 1 is subtracted from the power voltage V_{DDH}. At this time, the sense transistor 6 is also put into its conductive state simultaneously. Ignoring manufacturing variations and layout variations, if the power transistor 2 and the sense transistor 6 have gate lengths the same as each other, and the power transistor 2 and the sense transistor 6 are in a saturation region (also called a constant current region), then a current ratio of a drain current value of the sense transistor 6 to a drain current value of the power transistor 2 becomes substantially a ratio of the channel width of the sense transistor 6 to the channel width of the power transistor 2. However, in the current detection circuit of FIG. 1, the power transistor 2 and the sense transistor 6 are made to perform the switching operation, and therefore, the current ratio deviates largely from the channel width ratio due to an output impedance when there is a difference between the drain voltages of the power transistor 2 and the sense transistor 6 in the resistive region. The voltage control circuit 17 is provided to make the difference between the drain voltages of the power transistor 2 and the sense transistor 6 substantially zero by negative feedback. An electrical potential difference between the source and the gate of the output transistor 9 is controlled to become substantially constant, and the drain voltage of the sense transistor 6 is controlled to substantially coincide with the voltage at the non-inverted input terminal of the operational amplifier 8 by the negative feedback. Since the source current and the drain current of the output transistor 9 become to have values the same as each other, the drain current of the sense transistor 6 flows through the resistor 10. Therefore, the drain current of the sense transistor 6 is converted into a voltage generated at both ends of the resistor 10, and is detected.

Next, operation of the current detection circuit of FIG. 1 is described. First of all, it is assumed that an initial voltage of the electrostatic capacitor 12 is zero, and the gate voltage of the protecting MOSFET 7 is the same as the power voltage V_{DDL} in an initial state. When the power transistor 2 is put into its conductive state by the driver circuit 4 in the initial state, a drain current flows through the power transistor 2, and a drain voltage, that is lower than a drain voltage when the power transistor 2 is in its nonconductive state, is excited by a resistance component of the power transistor 2 when the power transistor 2 is in its nonconductive state. As a result, an electrical potential difference between the drain and the gate of the protecting MOSFET 7 exceeds a gate threshold voltage thereof, and the protecting MOSFET 7 is put into its conductive state. When the protecting MOSFET 7 is put into its conductive state, the electrostatic capacitor 12 is electrically charged via the diode 13. When the charging is substantially completed, the electrical potential difference between the source and the drain of the protecting MOSFET 7 becomes zero, and the gate voltage of the protecting MOSFET 7 becomes a voltage that is lower than the power voltage V_{DDL} by a forward bias voltage of the diode 13. That is, the voltage across both ends of the electrostatic capacitor 12 becomes a voltage of (power voltage V_{DDL}—forward bias voltage of diode 13—drain voltage of power transistor 2). When the charging of the electrostatic capacitor 12 is totally completed, the forward bias voltage of the diode 13 ideally becomes zero, and therefore, the gate voltage of the protecting MOSFET 7 becomes equal to the power voltage V_{DDL}.

When the drain voltage of the power transistor 2 increases from that of the above state as a possible consequence of an increase in the load current of the load 1, fluctuations in the electrical characteristics of the load 1, fluctuations in the power voltage V_{DDH} or the like, the source voltage also increases in a manner similar to above with the electrical potential difference between the source and the drain maintained at zero since the protecting MOSFET 7 is in its conductive state. Further, the gate voltage of the protecting MOSFET 7 also increases due to the voltage across both ends of the electrostatic capacitor 12. At this time, no current flows through the electrostatic capacitor 12 since the diode 13 is reversely biased, and the electric charge of the electrostatic capacitor 12 is maintained. Therefore, the gate-source voltage and the gate-drain voltage remain maintained in the protecting MOSFET 7, and the protecting MOSFET 7 remains in its conductive state with the respective voltages of equal to or larger than the gate threshold voltage maintained. Therefore, a voltage the same as the drain voltage of the power transistor 2 is applied to the non-inverted input terminal of the operational amplifier 8. Further, the drain voltage of the sense transistor 6 is controlled to substantially coincide with the source voltage (i.e., the drain voltage of the power transistor 2) of the protecting MOSFET 7 by the negative feedback. Therefore, the drain current ratio of the power transistor 2 to the sense transistor 6 becomes substantially equal to the channel width ratio of the power transistor 2 to the sense transistor 6, and the current flowing through the load 1 can be detected by the resistor 10 accurately.

Next, when the power transistor 2 is cut off by the driver circuit 4, the drain current of the power transistor 2 is cut off, and the drain voltage increases. On the other hand, the protecting MOSFET 7 remains in its conductive state due to a retained electric charge of the electrostatic capacitor 12, and therefore, a voltage the same as the drain voltage of the power transistor 2 is applied to the non-inverted input terminal of the operational amplifier 8. Next, when the drain voltage of the power transistor 2 further increases and the gate voltage of the protecting MOSFET 7 reaches the clamp voltage Vc of the voltage clamp circuit 14, the gate voltage of the protecting MOSFET 7 is clamped to the clamp voltage Vc. When a difference between the drain voltage of the power transistor 2 and the gate voltage of the protecting MOSFET 7 becomes smaller than the gate threshold voltage of the protecting MOSFET 7, the protecting MOSFET 7 is cut off. As a result, even when the drain voltage of the power transistor 2 further increases, the voltage at the non-inverted input terminal of the operational amplifier 8 is clamped to a voltage that is lower than the clamp voltage Vc by the gate threshold voltage of the protecting MOSFET 7.

Next, a setting method of the clamp voltage Vc of the voltage clamp circuit 14 is described. The clamp voltage Vc is set so that a voltage exceeding the withstand voltage of an input device of the operational amplifier 8 or a voltage exceeding a maximum in-phase input voltage at which the negative feedback operation cannot be performed in the operational amplifier 8 is not applied to the operational amplifier 8. Concretely speaking, the clamp voltage Vc is set to a voltage of equal to or smaller than a voltage of a sum of a maximum input operation voltage (maximum in-phase input voltage) of the operational amplifier 8 and the gate threshold voltage of the protecting MOSFET 7. By setting the clamp voltage Vc as described above, when the drain voltage of the power transistor 2 exceeds the maximum input operation voltage of the operational amplifier 8, the protecting MOSFET 7 is cut off, and the voltage at the non-inverted input terminal of the operational amplifier 8 is retained at a voltage of equal to or smaller than the maximum input operation voltage. Further, the clamp voltage Vc is set to a value larger than the gate threshold voltage of the protecting MOSFET 7. This is because the drain voltage of the power transistor 2 cannot be made larger than 0 V when the clamp voltage Vc is equal to or smaller than the gate threshold voltage of the protecting MOSFET 7.

According to the present preferred embodiment, each of the electrostatic capacitor 12 and the diode 13 requires only a withstand voltage similar to that of the operational amplifier 8, and only a minute transient current flows through each of the electrostatic capacitor 12 and the diode 13. Therefore, the current detection circuit can be manufactured compact by integrating the electrostatic capacitor 12 and the diode 13 with the operational amplifier 8. As a circuit configuration easily considered for supplying a high voltage to the gate of the protecting MOSFET 7, a circuit configuration such that the electrostatic capacitor 12 is connected not between the source and the gate of the protecting MOSFET 7 but between the drain and the gate of the protecting MOSFET 7 can be enumerated. However, in this case, the withstand voltage of the electrostatic capacitor 12 requires a high withstand voltage equal to that of the power transistor 2. In addition, an amplitude of the voltage applied to the electrostatic capacitor 12 becomes large, and therefore, a large transient current flows through each of the electrostatic capacitor 12, the diode 13 and the voltage clamp circuit 14 as compared with the circuit configuration of FIG. 1. Therefore, it becomes difficult to integrate the electrostatic capacitor 12 with other devices, and the capacitor must be an external device.

As described above, according to the present preferred embodiment, the power transistor 2 is pulse controlled, and the electrostatic capacitor 12 is electrically charged with an induced voltage of the load 1 generated when the power transistor 2 is cut off. When the power transistor 2 is in its conductive state, the source voltage of the protecting MOSFET 7 also increases according to the increase in the drain voltage of the power transistor 2. Therefore, the voltage of the electrostatic capacitor 12 is retained, and the gate voltage of the protecting MOSFET 7 also increases. Therefore, according to the current detection circuit of the present preferred embodiment, which includes the electrostatic capacitor 12 and the diode 13, a current proportional to the load current value can therefore be accurately detected to a relatively high voltage while satisfying the withstand voltage between the source and the gate of the protecting MOSFET 7. In addition, an input voltage range of the operational amplifier 8 can be extended from that of the prior art.

In addition, according to the present preferred embodiment, the gate threshold voltage increased by the substrate bias effect can be applied to the gate of the protecting MOSFET 7 in addition to the source voltage. Therefore, even when the substrate bias effect in the protecting MOSFET 7 is relatively large, the voltage outputted to the non-inverted input terminal of the operational amplifier 8 can be made larger than that of the prior art. In addition, since the diode 13 having a low withstand voltage and the electrostatic capacitor 12 having a low withstand voltage can be employed, integration of the current detection circuit can be easy and compacted as compared with the prior art.

### First Modified Preferred Embodiment of First Preferred Embodiment

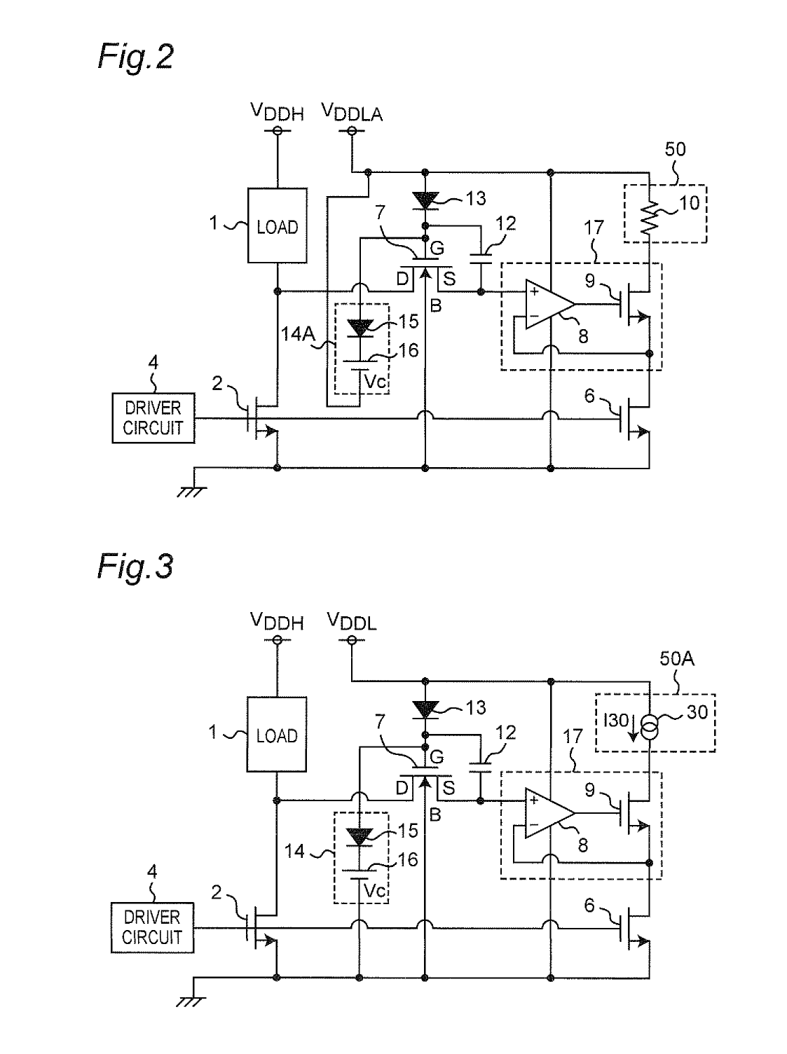

FIG. 2 is a circuit diagram of a current detection circuit according to the first modified preferred embodiment of the first preferred embodiment of the present invention. The present modified preferred embodiment is different from the first preferred embodiment in that a voltage clamp circuit 14A is provided in place of the voltage clamp circuit 14. Referring to FIG. 2, the voltage clamp circuit 14A is configured to include the diode 15 and the DC voltage source 16. In this case, the diode 15 has the anode connected to the gate of the protecting MOSFET 7 and the cathode connected to a voltage source, which outputs a power voltage V_{DDLA}, via the DC voltage source 16. In this case, the power voltage V_{DDLA} has a sine waveform. In contrast to the first preferred embodiment in which the clamp voltage Vc of the voltage clamp circuit 14 is a fixed voltage generated relative to the ground potential of the reference electric potential, the clamp voltage Vc of the present modified preferred embodiment is a voltage having a sine waveform generated relative to the power voltage V_{DDLA} of a reference voltage.

Therefore, according to the present modified preferred embodiment, the clamp voltage Vc that fluctuates in a manner similar to that of the power voltage V_{DDLA} can be generated even when the power voltage V_{DDLA} fluctuates. It is noted that the power voltage V_{DDLA} may be a fixed voltage.

### Second Modified Preferred Embodiment of First Preferred Embodiment

FIG. 3 is a circuit diagram of a current detection circuit according to the second modified preferred embodiment of the first preferred embodiment of the present invention. The present modified preferred embodiment is characterized in that a detector circuit 50A is provided in place of the detector circuit 50 as compared with the first preferred embodiment. In this case, the detector circuit 50A is configured to include a constant current source 30 that outputs a current having a constant current value I30. The constant current source 30 constitutes a current comparator. Referring to FIG. 3, the drain of the output transistor 9 is connected to the voltage source, which outputs the power voltage V_{DDL}, via the constant current source 30. According to the present modified preferred embodiment, the drain voltage of the output transistor 9 decreases when the current value of the drain current of the sense transistor 6 is larger than the constant current value I30. Conversely, the output transistor 9 is cut off when the current value of the drain current of the sense transistor 6 is smaller than the constant current value I30, and the drain voltage of the output transistor 9 increases. Therefore, the load current of the load 1 can be detected by detecting the drain voltage of the output transistor 9 in the detector circuit 50A.

The present modified preferred embodiment exhibits action and advantageous effects similar to those of the first preferred embodiment. It is noted that the configuration of the current comparator is not limited to the configuration of FIG. 3. For example, it is acceptable to provide a current mirror circuit for mirroring and outputting the drain current of the output transistor 9, and a current comparator for comparing a current outputted from the current mirror circuit with a predetermined constant current value and outputting a signal representing a comparison result.

### Third Modified Preferred Embodiment of First Preferred Embodiment

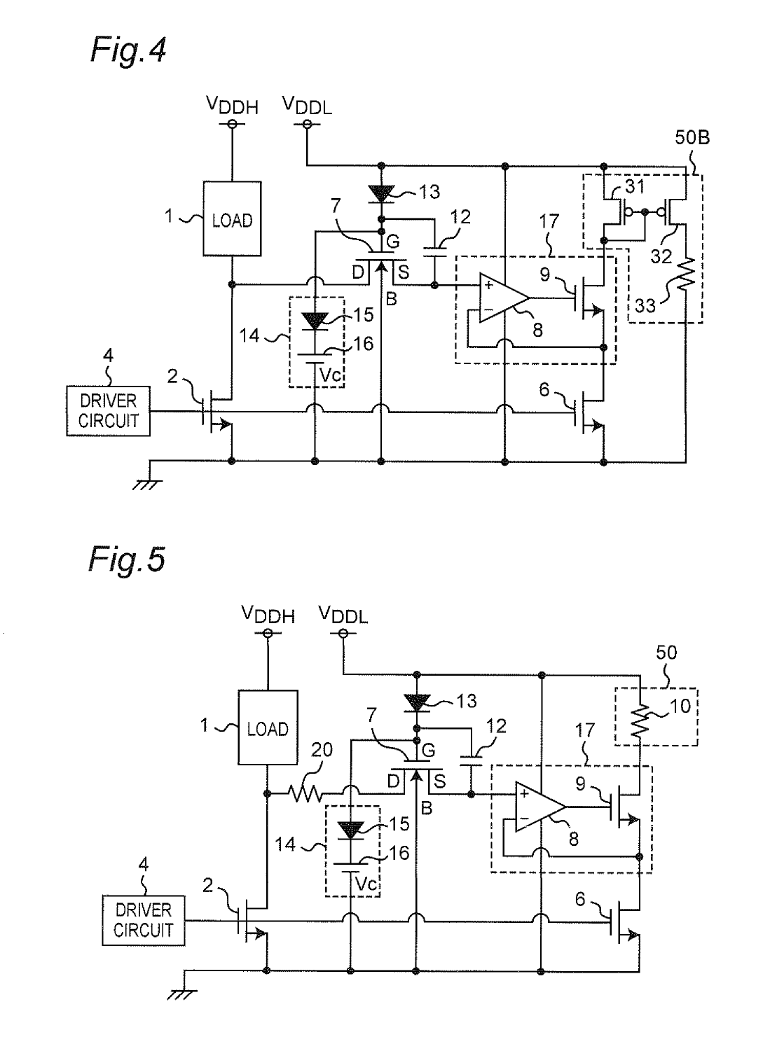

FIG. 4 is a circuit diagram of a current detection circuit according to the third modified preferred embodiment of the first preferred embodiment of the present invention. The present modified preferred embodiment is characterized in that a detector circuit 50B including p-channel type MOSFETs 31 and 32, which constitute a current mirror circuit, and a resistor 33 is provided in place of the detector circuit 50 as compared with the first preferred embodiment. Referring to FIG. 4, the p-channel type MOSFET 31 has a source connected to the drain of the output transistor 9, a drain connected to the voltage source that outputs the power voltage V_{DDL}, and a gate connected to the source the p-channel type MOSFET 31 and a gate of the p-channel type MOSFET 32. The p-channel type MOSFET 32 has a drain connected to the voltage source that outputs the power voltage V_{DDL}, and a source grounded via the resistor 33. In this case, the p-channel type MOSFETs 31 and 32 have structures the same as each other and sizes the same as each other. Therefore, a current flowing through the source of the p-channel type MOSFET 32 becomes the same as the current value of the drain current of the output transistor 9. Therefore, by detecting an electrical potential at one end of the resistor 33, the load current of the load 1 can be detected based on a voltage that is dropped by the voltage drop due to the resistor 33 from the source voltage of the p-channel type MOSFET 32.

The present modified preferred embodiment exhibits action and advantageous effects similar to those of the first preferred embodiment. It is noted that the configuration of the current mirror circuit is not limited to the configuration of FIG. 4.

### Fourth Modified Preferred Embodiment of First Preferred Embodiment

FIG. 5 is a circuit diagram of a current detection circuit according to the fourth modified preferred embodiment of the first preferred embodiment. When the integrated circuit of the current detection circuit of the first preferred embodiment is manufactured by junction isolation, a body of the protecting MOSFET 7 has the ground potential. Therefore, when the load 1 is an inductive load of a motor drive or the like, the drain voltage of the protecting MOSFET 7 becomes smaller than the ground potential. When the junction between the body and the drain of the MOSFET 7 is forwardly biased, a large current flows through the junction, possibly causing the malfunction or damage of the integrated circuit. As shown in FIG. 5, in order to lessen the current in the present modified preferred embodiment, a resistor 20 is connected between a connecting point of the drain of the power transistor 2 and the load 1, and the drain of the protecting MOSFET 7. When the drain voltage of the protecting MOSFET 7 becomes larger than the ground potential, only a transient charging current of the electrostatic capacitor 12 flows through the resistor 20. It is noted that the resistor 20 may be integrated with the other devices of the current detection circuit or connected to an external part of the integrated circuit of the current detection circuit.

### Fifth Modified Preferred Embodiment of First Preferred Embodiment

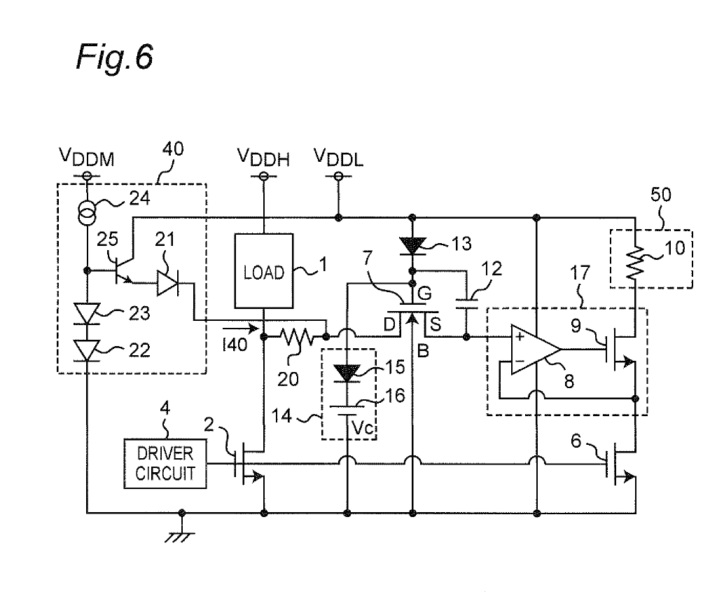

FIG. 6 is a circuit diagram of a current detection circuit according to the fifth modified preferred embodiment of the first preferred embodiment. The current detection circuit of the present modified preferred embodiment is characterized in that a current supply circuit 40 having high withstand voltage diodes 21, 22 and 23, a constant current source 24 and an npn transistor 25 is further provided as compared with the current detection circuit of the fourth modified preferred embodiment of the first preferred embodiment. Referring to FIG. 6, the constant current source 24 has one end connected to a voltage source that outputs an output voltage V_{DDM} of, for example, several tens of volts, and another end grounded via the high withstand voltage diodes 22 and 23. The npn transistor 25 has a base connected to a connecting point between the constant current source 24 and the high withstand voltage diode 23, an emitter connected to the drain of the protecting MOSFET 7 via the high withstand voltage diode 21, and a collector connected to the voltage source that outputs an output voltage V_{DDL}. The current supply circuit outputs a constant current having a current value I40. It is noted that the current value I40 is set to a maximum current value for preventing the damage of the protecting MOSFET 7. Therefore, according to the present modified preferred embodiment, the current value of the current flowing through a connecting point between the body and the drain of the protecting MOSFET 7 becomes substantially the current value 140, and therefore, the possibility of causing the malfunction and damage of the integrated circuit can be further reduced as compared with the fourth modified preferred embodiment of the first preferred embodiment.

In each of the first preferred embodiment and the modified preferred embodiments of the first preferred embodiment described above, the power voltage V_{DDH} has a fixed value, however, the present invention is not limited to this. The power voltage V_{DDH} is not required to have a fixed value. For example, in a case where a bridge circuit is constituted by employing the power transistor 2 and another power transistor, the above another power transistor is connected to the load 1 instead of the voltage source that outputs the power voltage V_{DDH}.

### Second Preferred Embodiment

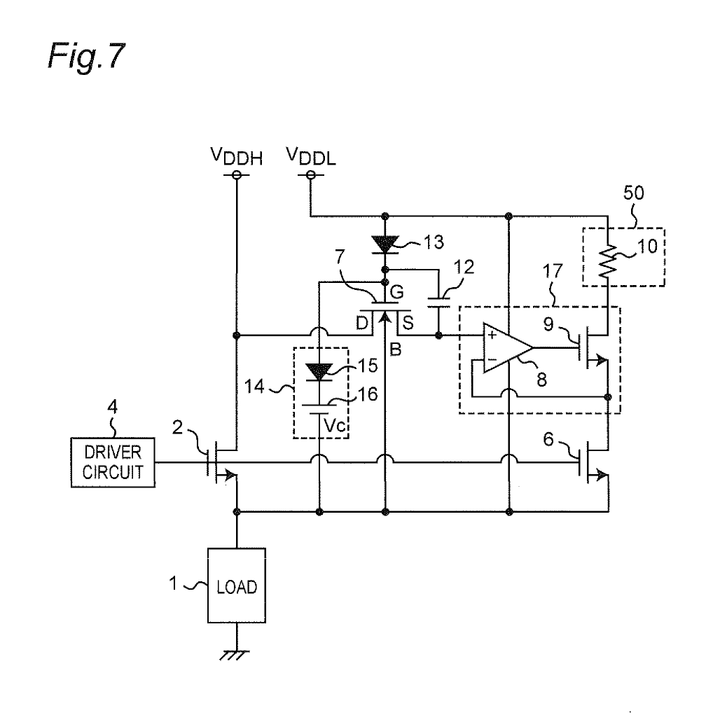

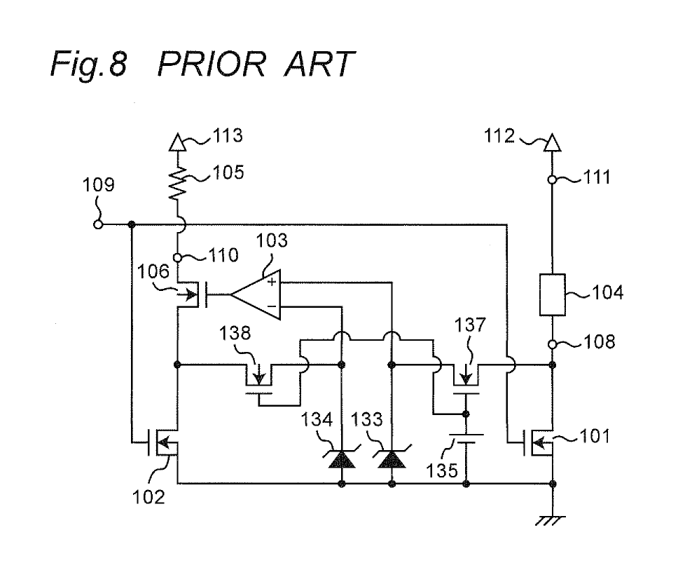

FIG. 7 is a circuit diagram of a current detection circuit according to the second preferred embodiment of the present invention. The present preferred embodiment is different from the first preferred embodiment in that the load 1 is connected between the source of the power transistor 2 and the ground potential. In addition, a connecting point between the drain of the power transistor 2 and the protecting MOSFET 7 is directly connected to the voltage source that outputs the power voltage V_{DDH}, not via the load 1. Referring to FIG. 7, when the power transistor 2 is put into its conductive state by the driver circuit 4, a drain current flows through the power transistor 2, and a drain voltage, that is lower than the drain voltage when the power transistor 2 is in its nonconductive state, is excited by a resistance component of the power transistor 2 when the power transistor 2 is in its nonconductive state, in a manner similar to that of the first preferred embodiment Then, the voltage between the source and the drain of the power transistor 2 is decreased, and an electrical potential difference between the drain and the gate of the protecting MOSFET 7 exceeds the gate threshold voltage, so that the protecting MOSFET 7 is put into its conductive state. When the protecting MOSFET 7 is put into its conductive state, the electrostatic capacitor 12 is electrically charged via the diode 13. Subsequently, in a manner similar to that of the first preferred embodiment, the protecting MOSFET 7 is controlled to be in its conductive state or cut off according to an increase in the drain voltage of the power transistor 2, and the drain voltage of the sense transistor 6 is controlled to substantially coincide with the drain voltage of the power transistor 2. If each of the circuit currents of the operational amplifier 8 and the voltage clamp circuit 14 is sufficiently smaller than the load current of the load 1, then a current of the sum of the drain current of the power transistor 2 and the drain current of the sense transistor 6 is supplied to the load 1.

The present preferred embodiment exhibits action and advantageous effects similar to those of the first preferred embodiment. In the present preferred embodiment, one end of the load 1 is grounded, and another end is connected to the source of the power transistor 2, however, the present invention is not limited to this. The electrical potential at the one end of the load 1 is not necessarily required to have a fixed value. For example, in a case where a bridge circuit is constituted by employing the power transistor 2 and another power transistor, the above another power transistor is connected to the load 1.

In each of the preferred embodiments and the modified preferred embodiments, it is acceptable to connect another clamp circuit that has a clamp voltage of equal to or smaller than the maximum input operation voltage of the operational amplifier 8 additionally to the non-inverted input terminal of the operational amplifier 8 in order to reliably retain the voltage at the non-inverted input terminal of the operational amplifier 8 to a voltage of equal to or smaller than the maximum input operation voltage. In this case, it is desirable to set the clamp voltage Vc of the voltage clamp circuit 14 or 14A to a value of equal to or smaller than a voltage such that the gate threshold voltage of the protecting MOSFET 7 is added to the clamp voltage of the clamp circuit described above. This is because, when the clamp voltage Vc of the voltage clamp circuit 14 or 14A is set higher than the voltage such that the gate threshold voltage of the protecting MOSFET 7 is added to the clamp voltage of the additional clamp circuit, the power transistor 2 is cut off to make the drain voltage of the power transistor 2 higher than the clamp voltage of the additional clamp circuit, consequently making the protecting MOSFET 7 conductive and flowing a current through the additional clamp circuit and the protecting MOSFET 7 to increase the consumption current.

In addition, in each of the preferred embodiments and the modified preferred embodiments, the current detection circuit is wholly integrated into the integrated circuit, however, the present invention is not limited to this. In small-power applications, it is preferable to integrate together all of the devices and circuits except for the load 1. In addition, in high-power applications, by integrating the devices except for the load 1, the power transistor 2 and the sense transistor 6 into an integrated circuit, and connecting the load 1, the power transistor 2 and the sense transistor 6 to an external part of the integrated circuit, it is possible to make a temperature rise caused by power loss less influential directly on the integrated circuit. Further, in the high-voltage applications, it is preferable to integrate the devices except for the load 1, the power transistor 2, the sense transistor 6 and the protecting MOSFET 7 into an integrated circuit, and to connect the load 1, the power transistor 2, the sense transistor 6 and the protecting MOSFET 7 to an external part of the integrated circuit. With this arrangement, even when the power voltage V_{DDH} is a high voltage that exceeds the withstand voltage of the integrated circuit, no high voltage is applied to the non-inverted input terminal of the operational amplifier 8, and therefore, the integrated circuit can be manufactured by using low withstand voltage semiconductor circuit manufacturing processes. By using the low withstand voltage processes, the current detection circuit can be made compact and inexpensive.

Further, in each of the preferred embodiments and the modified preferred embodiments, the power transistor 2 is the n-channel type MOS device, however, the present invention is not limited to this. The device is only required to be a semiconductor device such as an IGBT, a power MOSFET, a BJT or a wide bandgap semiconductor using silicon carbide or gallium nitride, which can perform switching operation (conduction and cutoff) by the driver circuit 4. In this case, the power transistor 2 is only required to be a first semiconductor device, which has a first terminal, a second terminal and a first current control terminal, where a current flowing between the first and second terminals is controlled by a control voltage applied to the first current control terminal. The sense transistor 6 is only required to be a second semiconductor device, which has a third terminal connected to the first terminal, a fourth terminal and a second current control terminal, where a current flowing between the third and fourth terminals is controlled by the control voltage applied to the second current control terminal.

Still further, in each of the preferred embodiments and the modified preferred embodiments, the source follower circuit is configured to include the output transistor 9 of the n-channel type MOSFET, however, the present invention is not limited to this, and an emitter follower may be configured to include an n-type bipolar transistor.

In addition, in each of the preferred embodiments and the modified preferred embodiments, a rectifying element such as an FET diode connection circuit, which flows a current only in one direction, may be employed in place of the diode 13.

Further, in each of the preferred embodiments and the modified preferred embodiments, the protecting MOSFET 7 is the enhancement type MOSFET, however, the present invention is not limited to this, and a depression type MOSFET is acceptable.

Still further, in each of the preferred embodiments and the modified preferred embodiments, the driver circuit 4 is integrated with the other devices of the current detection circuit, however, the driver circuit 4 may be provided in an external part of the integrated circuit of the current detection circuit.

In addition, in each of the preferred embodiments and the modified preferred embodiments, the voltage control circuit 17 has the operational amplifier 8 and the output transistor 9, however, the present invention is not limited to this. The circuit may have another circuit configuration for executing control so that the drain voltage of the sense transistor 6 is made to coincide substantially with the source voltage of the protecting MOSFET 7.

As described above in detail, according to the current detection circuit of the present invention, the circuit includes the followings:

(a) the MOSFET transistor having the drain connected to the second terminal of the first semiconductor device, the source and the gate, where current flowing between the drain and the source is controlled by the voltage applied to the gate;

(b) the electrostatic capacitor having one end connected to the source of the MOSFET transistor and another end connected to the gate of the MOSFET transistor;

(c) the rectifier device having a cathode connected to the gate of the MOSFET transistor and an anode connected to the first voltage source for outputting the predetermined first power voltage; and

(d) the voltage clamp circuit connected to the gate of the MOSFET transistor, where the voltage clamp circuit clamping the maximum voltage of the gate of the MOSFET transistor to the predetermined clamp voltage.

With this arrangement, it is possible to apply a gate threshold voltage, which is increased by the substrate bias effect, to the gate of the MOSFET transistor in addition to the source voltage. Therefore, even when the substrate bias effect in the MOSFET transistor is relatively large, the load current can be detected with an accuracy higher than that of the prior art with exercising negative feedback to the relatively high voltage while satisfying the withstand voltage between the source and the gate of the MOSFET transistor.

The current detection circuit of the present invention is useful for detection of the current that flows through the power transistor driven pulse wise.

Although the present invention has been fully described in connection with the preferred embodiments thereof with reference to the accompanying drawings, it is to be noted that various changes and modifications are apparent to those skilled in the art. Such changes and modifications are to be understood as included within the scope of the present invention as defined by the appended claims unless they depart therefrom.

What is claimed is:

1. A current detection circuit comprising:
a first semiconductor device having a first terminal, a second terminal, and a first current control terminal, a current flowing between the first and second terminals being controlled by a control voltage applied to the first current control terminal;
a second semiconductor device having a third terminal connected to the first terminal, a fourth terminal, and a second current control terminal the second semiconductor device having a structure substantially the same as a structure of the first semiconductor device, a current flowing between the third and fourth terminals being controlled by the control voltage applied to the second current control terminal;
a MOS field-effect transistor having a drain connected to the second terminal of the first semiconductor device, a source, and a gate, a current flowing between the drain and the source being controlled by a voltage applied to the gate;
an electrostatic capacitor having one end connected to the source of the MOS field-effect transistor, and another end connected to the gate of the MOS field-effect transistor;
a rectifying element having a cathode connected to the gate of the MOS field-effect transistor and an anode connected to a first voltage source for outputting a predetermined first power voltage;
a voltage clamp circuit connected to the gate of the MOS field-effect transistor, the voltage clamp circuit clamping a maximum voltage of the gate of the MOS field-effect transistor to a predetermined clamp voltage;
a voltage control circuit for controlling a voltage at the fourth terminal of the second semiconductor device so as to substantially coincides with a source voltage of the MOS field-effect transistor; and
a detector circuit for detecting a current flowing through the fourth terminal of the second semiconductor device.

2. The current detection circuit as claimed in claim 1, further comprising a load connected to the second terminal of the first semiconductor device,
wherein the first terminal of the first semiconductor device and the third terminal of the second semiconductor device are grounded.

3. The current detection circuit as claimed in claim 1, further comprising a load connected to the first terminal of the first semiconductor device,
wherein the second terminal of the first semiconductor device and the drain of the MOS field-effect transistor are connected to a second voltage source for outputting a predetermined second power voltage.

4. The current detection circuit as claimed in claim 1, further comprising a driver circuit for applying the control voltage to the first and second current control terminals.

5. The current detection circuit as claimed in claim 2, further comprising a driver circuit for applying the control voltage to the first and second current control terminals.

6. The current detection circuit as claimed in claim 3, further comprising a driver circuit for applying the control voltage to the first and second current control terminals.

7. The current detection circuit as claimed in claim 1,
wherein the voltage control circuit comprises:
an operational amplifier having a non-inverted input terminal connected to the source of the MOS field-effect transistor, an inverted input terminal connected to the fourth terminal of the second semiconductor device, and an output terminal; and
an output transistor having a fifth terminal connected to the fourth terminal of the second semiconductor device, a sixth terminal connected to the detector circuit, and a third current control terminal connected to the output terminal of the operational amplifier, a current flowing between the fifth and sixth terminals being controlled by a voltage applied from the operational amplifier to the third current control terminal.
